(19) United States
(12) Patent Application Publication
(10) Pub. No.: US 2011/0012125 A1
(43) Pub. Date: Jan. 20, 2011

(54) THIN FILM TRANSISTOR AND ACTIVE MATRIX DISPLAY

(76) Inventors: Gareth Nicholas, Oxford (GB); Benjamin James Hadwen, Oxford (GB); Sunay Shah, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/933,450

(22) PCT Filed: Apr. 20, 2009
(86) PCT No.: PCT/JP2009/058219

§ 371 Date: Sep. 20, 2010

(30) Foreign Application Priority Data
Apr. 29, 2008 (GB) 0807766.1

(51) Int. Cl. H01L 33/00; H01L 29/786

(52) U.S. Cl. 257/72; 257/347; 257/E29.273; 257/E33.001

(57) ABSTRACT

A thin film transistor is formed in a semiconductor island on an insulating substrate. The transistor comprises a source (1502) and a drain (1504) of first conductivity type and a channel (1508) of a second opposite conductivity type. The channel is overlapped by one or more insulated gates (1510) and is provided with isolation diodes. Each isolation diode comprises a first region (1506) which is lightly doped and a second region (1512) which is heavily doped and of the second conductivity type. The diodes are not overlapped by the gate (1510). The first and second regions (1506, 1512) extend away from the channel (1508) by less than the length of the adjacent source or drain. The lightly doped region (1506) extends away from the source or drain and the heavily doped region (1512) extends away from the lightly doped region such that the first and second regions (1506, 1512) form a p-n junction with the adjacent source or drain in a direction orthogonal to the main conduction path of the transistor but not parallel to the main conduction path.

### TECHNICAL FIELD

This invention relates to thin film transistors (TFTs), for example of a type that are fabricated in the manufacture of the display substrate of an active matrix liquid crystal display (AMLCD). The present invention also relates to active matrix displays including such transistors.

### BACKGROUND ART

FIG. 1 of the accompanying drawings shows an AMLCD substrate. In the display pixel matrix 102, TFTs are located next to each pixel, or sub-pixel in the case of a colour display, to control the level of light emitted. TFTs are also widely used in the display gate and source drivers 104 and 106, respectively, and may also be employed in sensor driver circuits 108. Many products utilise such AMLCDs (e.g. mobile phones and personal digital assistants (PDAs)). An improvement in the electrical characteristics of the TFTs enables the power consumption of an AMLCD to be minimised, or alternatively enables higher performance. TFTs also find application in circuits for “system on panel” applications such as ambient light sensors and temperature sensors. Certain preferred circuit topologies that enable these applications, such as low power amplifiers, are feasible only if the TFT electrical characteristics are sufficiently uniform.

The TFT is a variant of the metal-oxide-semiconductor field effect transistor (MOSFET), which consists of two semiconductor diodes placed back to back and a capacitor formed between the semiconductor and a gate electrode that controls the current flow between the diodes. The structure of semiconductor diodes and transistors is well known [Y. Taur and T. K. Ning, “Fundamentals of Modern VLSI Devices,” Cambridge University Press, 1998] and will not be described here. The difference between a TFT and a conventional MOSFET is that in a TFT the semiconductor takes the form of a thin film placed on an insulating substrate, rather than the entire substrate being comprised of the semiconductor material.

FIG. 2 of the accompanying drawings shows a typical TFT, with the top-gate configuration (gate electrode 202 positioned above the semiconductor). The structure would typically be covered with a dielectric (e.g. SiO₂) that has been omitted from the diagram for clarity. The fabrication processes for the various types of TFT are well known but are outlined here. A base coat (typically SiO₂) is deposited on the substrate (typically glass, but other materials including quartz and plastics may be used). If the final device is to incorporate a gate electrode below the channel, the gate material (usually a metal such as TiN, TaN, W or Mo, or sometimes poly Si) is deposited and patterned, followed by the deposition of a thin insulator layer (typically a few tens of nm of SiO₂). The semiconductor (most likely Si) is deposited and patterned. It is usual for each TFT to be created in an individual semiconductor island on the insulating basecoat. Because each TFT is thus isolated, problems such as cross talk between adjacent devices are removed.

The most common technique for patterning the semiconductor and other layers in the fabrication of a TFT is lithography. A light-sensitive chemical known as a photo resist is spun onto a deposited layer and then exposed to ultraviolet light whilst covered with a mask, so that only certain defined regions of the photo resist may react with the light. The resist is then developed so that either the regions that were exposed or those that weren't are removed (depending on whether the resist used is “positive” or “negative”). The deposited layer may then be etched; the regions still covered by photo resist are protected from this process. The remaining resist is then removed. Since the fabrication of TFTs requires several such masking steps, all subsequent masks must be precisely aligned to the first. There will however always be unavoidable small errors in alignment, the magnitude of which depends on the accuracy of the mask aligner used. These errors must be accounted for in the design of the TFT.

At this point, a treatment such as laser annealing may be used to crystallise the semiconductor if it was deposited in the amorphous state, and the semiconductor may be doped by ion implantation or diffusion. If the TFT is to incorporate a gate electrode above the channel, a thin insulator layer and gate material are then deposited and patterned. The source and drain regions are formed (typically by ion implantation) so that they are heavily doped with an opposite polarity to the semiconductor material between them. For top-gate TFTs, the presence of the gate electrode serves to block implanted ions, so that they are only introduced to the semiconductor adjacent to it. This is known as a self-aligned implant. For non self-aligned implants, a developed photo resist is relied upon to block the dopant ions where they are not required.

Diodes are formed at the junctions between semiconducting material of opposite doping polarities, so that a TFT contains two diodes, one at the junction between the source implant and the channel underneath the gate, and one at the junction between the drain implant and the channel. In an n-type semiconductor there is an excess of negative charge carriers (electrons), whilst in a p-type semiconductor there is an excess of positive charge carriers (holes). When the two types are brought together, excess electrons and holes diffuse across the junction and recombine with carriers of the opposite type. The removal of these free carriers leaves positively charged ions in the n-type region and negatively charged ions in the p-type region near the junction. This is known as a depletion region, and the presence of the charged ions sets up an electric field that causes charge carriers to drift in the opposite direction to those that are diffusing across the junction. Equilibrium is reached when the current due to carrier drift equals that due to carrier diffusion. The width of the depletion region depends on the doping concentration in the two types of semiconductor. The depletion region is widest in semiconductors with a low concentration of dopants. The electric field strength will also be reduced in such a case. There is a small but non-zero capacitance associated with the depletion region of a diode, since the p and n-type regions may be thought of as the two electrodes of a capacitor, with the depletion region acting as the dielectric.

When a diode is forward biased, the n-type material is negatively biased with respect to the p-type material. This reduces the electric field strength across the depletion region and disturbs the equilibrium so that the diffusion current becomes larger than the drift current. Because the current flow is dominated by diffusion, there is an exponential dependence of current on applied voltage. Large currents can therefore flow through the diode for even relatively small applied forward biases.

In a diode under reverse bias, the n-type material is positively biased with respect to the p-type material. This increases the strength of the electric field across the depletion region and favours drift current over diffusion. Because electrons and holes are in short supply in the p-type and n-type material, respectively, the current through the diode remains extremely small, however. The width of the depletion region increases as the reverse bias is increased, as more carriers recombine to accommodate the potential drop across the junction. Because of the increased depletion region size and electric field, diodes in reverse bias are sensitive to processes that create electron-hole pairs, such as illumination. Carriers generated by such a process will immediately be swept out of the depletion region by the electric field and a leakage current is observed through the diode.

In a complementary process, both n-channel TFTs (nTFTs) and p-channel (pTFTs) are created, so that at least two doping steps are required. For example, the nTFT source and drain regions may be formed by a phosphor (n-type) implant whilst the pTFTs are masked by photoresist. The pTFT source and drain regions may then be formed by a boron (p-type) implant with the nTFTs masked.

The TFT fabrication is completed by opening holes in a deposited dielectric (typically SiO₂ or SiN) and depositing and patterning metal contacts for the source, drain and gate electrodes. The formation of these contacts necessarily requires a certain minimum area of semiconductor in the contact region.

Because the substrate used for the TFT backplane is usually glass, there is a requirement to keep temperatures relatively low (below approximately 600° C.) throughout the fabrication process in order to minimise shrinkage and melting. Alternative substrate materials such as plastic have even more stringent maximum temperature limitations.

The most common type of TFT employs a top-gate, for which gate electrodes are deposited subsequent to the formation of semiconductor islands and run across the entire width of each island, being contacted elsewhere. Consequently, there may be regions where the gate electrode wraps around the edge of the island, due to the difference in height of the island and the surrounding basecoat region. TFTs may also be fabricated with a gate electrode below the semiconductor, or with gate electrodes both above and below the semiconductor. FIG. 3 of the accompanying drawings shows a cross-section through such an nTFT with two gate electrodes in the channel length direction (equivalent to the y direction in FIG. 2). Either of these gate electrodes may be left floating, rather than being connected to a power supply.

The width of the TFT channel (x direction, parallel to the gate electrode in FIG. 2) depends on the application of the device. To minimise the area required for integrated circuitry, it is generally desirable to make the TFT as small as possible. The current that flows through the TFT is proportional to the channel width however, so that for some applications the TFT width must remain relatively large. For logic applications, the channel width can generally be narrower, and the limiting factor becomes the area required for the region where the metal source and drain electrodes contact the semiconductor. In such a case, the semiconductor island may be patterned as shown in FIG. 4 of the accompanying drawings.

FIG. 5 of the accompanying drawings shows a cross-section through a top-gate nTFT in the channel length direction. In typical operation, the source 502 is grounded, and the drain 504 is biased at a high voltage. The junction between the channel 508 and drain is therefore reverse biased. The potential of the gate electrode 506 determines whether or not current flows between the source and drain, thus giving rise to the switching operation of a TFT. With the gate electrode at a low potential (off state), the weakly p-type doped channel region acts as a barrier to conduction between the heavily n-type doped source and drain regions. With the gate electrode at a high potential (on state), the surface of the channel region is inverted so that a thin layer of free electrons is created that enables current flow between source and drain. The gate voltage at which the surface of the channel first inverts is known as the threshold voltage. pTFTs operate in the same fashion, except that the polarity of all dopants and applied potentials is reversed, and conduction takes place by means of holes rather than electrons. Typical transfer characteristics for an nTFT and pTFT are shown in FIG. 6 of the accompanying drawings, illustrating how the current at the drain varies according to the potential on the gate.

Because the drain of a TFT is reverse biased, the electric field may be large enough to cause undesirable impact ionisation in the region of the channel near the junction. When conduction carriers encounter a large electric field, they may gain much more energy than normal, becoming hot carriers. Hot carriers may have sufficient energy to create damage within the semiconductor or surrounding insulator (or at the interface between them), which degrades the performance of the TFT over time. To reduce the electric field at the drain and hence reduce the number of hot carriers, lightly doped drain (LDD) or gate overlapped drain (GOLD) structures may be employed. The creation of LDD or GOLD structures requires an additional ion implantation step, and in the case of LDD structures this implant may be global (i.e. not masked with resist).

FIG. 7 of the accompanying drawings shows nTFTs with LDD and GOLD structures. The structures take the form of additional regions of n-type doping inserted between the heavily doped n-type source/drain regions and the p-type channel. The additional regions have a doping concentration that is lower than in the source and drain regions. Because the potential varies more gradually across such a junction, the electric field strength is reduced. For LDD structures 702, the additional n-type regions are placed adjacent to the gate electrode whereas, for GOLD structures 704, the additional regions are positioned underneath the gate electrode.

The TFT semiconductor island is surrounded on all sides by an insulator such as SiO₂, which may contain fixed charge (either positive or negative) because of requirements for low temperature fabrication. The presence of fixed positive charge will cause p-type semiconductor material to invert at a smaller gate voltage than otherwise, whilst negative oxide charge will likewise cause n-type material to invert at a smaller gate voltage. It is thought that, because the edges of the semiconductor island are exposed to more of the insulator, the threshold voltage may be particularly small in these regions. In addition, if the TFT is of the top-gate configuration with the gate electrode wrapped around the side of the semiconductor island, the electric field strength between the gate and the semiconductor will be greater at the island edges than the centre upon application of a potential difference between the gate and source electrodes. This also has the effect of reducing the threshold voltage of the island edges.

The early turn-on of the edge regions of the island is seen as a leakage current in the transistor subthreshold region, as shown for the nTFT in FIG. 8 of the accompanying drawings. A TFT with such leakage at the island edges may be modeled as two transistors in parallel, one representing the island edge parasitic transistors 902, and one representing the main body of the TFT 904, as shown in FIG. 9 of the accompanying drawings. In order to ensure that the island edges are off when the gate electrode is at the source potential, the threshold voltage of the TFT must be increased, usually by increasing the concentration of the channel doping. This increases the magnitude of the supply voltage required to realise acceptable on and off currents, and consequently increases the power consumption of any circuit utilising TFTs. The presence of the subthreshold leakage current also has the effect of increasing the variance between TFTs in this regime of operation. Certain circuit topologies, such as low power amplifiers, rely on TFTs having well matched subthreshold currents. The variance introduced by the parasitic conducting channels at the island edge means that the performance of such circuits is reduced.

It is known that increasing the concentration of the channel doping only in the vicinity of the channel edges can help to reduce the leakage current associated with parasitic conduction in these regions. For example, U.S. Pat. No. 5,488,001 discloses a technique for manufacturing TFTs with high-doped stripes created at the island edges by means of an ion implantation mask with beveled edges. Such a technique necessarily requires modification of established TFT fabrication process flows, which will increase cost and may adversely impact yield. Furthermore, since the regions with increased doping concentration directly contact the highly doped source and drain regions, which have opposite doping polarity to the channel, it is likely that strong lateral electric fields will result, increasing junction leakage at the drain and degrading reliability.

An alternative approach is to create diodes at the edges of the semiconductor island that prevent the parasitic conduction paths underneath the gate electrode from communicating with the source and drain regions. FIG. 10 of the accompanying drawings shows a plan view of a TFT with isolation diodes created using doping regions of opposite polarity to the source 1002 and drain 1004, as disclosed in U.S. Pat. No. 4,791,464. In the case of an nTFT, the diodes are created using two p-type doped semiconductor regions. The weakly p-type doped region (known as p− doping) 1006 acts to reduce the strength of the electric field within the diode, while the heavily p-type doped region (known as p+ doping) 1008 acts to restrict the size of the depletion region that forms within the p-type side of the diode. The regions 1006 and 1008 form p-n junctions 1014 and 1016 with the source 1002 and the drain 1004. The junction 1014 is formed in a first direction y parallel to the main conduction path of the TFT whereas the junction 1016 is formed in a second direction x orthogonal to the first direction. The presence of diodes 1102 causes the parasitic transistors 1104 to be isolated from the source 1106 and drain 1108, as shown in the equivalent circuit in FIG. 11 of the accompanying drawings.

The problem with this approach is that the additional depletion regions of the isolation diodes will add to the parasitic capacitance associated with the source and drain junctions, degrading high frequency operation of the TFT. In addition, these depletion regions will be sensitive to carrier generation through exposure to light. This may make a device incorporating such structures unsuitable for use in a display, due to increased junction leakage in the reverse biased diode limiting the off state current that can be achieved. Furthermore, such a device may show increased sensitivity to temperature through elevated leakage in the isolation diodes at high temperatures. Finally, when manufacturing such a transistor, it is necessary to use at least two implant steps that employ masks which are not self-aligned with respect to one another to create the n+ and p+ doped regions of the isolation diodes. Consequently, the TFT fabrication is made more challenging by the requirement that the implant masks should be precisely aligned in both the x and the y directions, as shown in FIG. 12 of the accompanying drawings. Failure to achieve sufficiently accurate alignment can result in the separation between the n+ and p+ regions becoming too small, which will result in increased electric field strength in the diode due to the abruptly changing potential across the junction and greatly increased junction leakage.

Another approach is to fabricate the TFT in such a way that the gate electrode does not overlap the edges of the semiconductor island. U.S. Pat. No. 4,918,498 describes a device in which the gate electrode terminates above regions with the opposite doping polarity to the source and drain regions. The drawback of this approach is that a metal contact must be made to the gate electrode directly above the semiconductor island, rather then elsewhere in the circuit. This requires that the gate electrode must have a region with a sufficiently large area that a contact to it can be reliably formed. The total area of the TFT will be unavoidably increased, which is highly undesirable when integrated circuits should consume as little area as possible. In addition, the greater area of gate electrode above the device may result in increased leakage current from the gate electrode.

Other relevant prior art includes disclosures concerning the addition of regions to transistors that may be used to ground the body of the device. Because the channel region of a conventional TFT is floating, it is possible for its potential to change as a result of a build-up of carriers generated by impact ionisation at the drain. This can lead to the kink effect, when the drain current of the TFT increases significantly as the drain voltage increases, rather than saturating, as expected for a well-behaved transistor [Y. Taur and T. K. Ning, “Fundamentals of Modern VLSI Devices,” Cambridge University Press, 1998]. This is detrimental to device reliability.

FIG. 13 of the accompanying drawings shows prior art from U.S. Pat. No. 6,940,138, in which regions of opposite doping polarity to the source and drain are added along the sides of the transistor in the channel length direction and contacted with metal lines. Although the purpose of such designs is to facilitate the removal of excess carriers and thus improve transistor reliability, it is likely that they would also prove beneficial in the reduction of the leakage current associated with the semiconductor island edges. The problems associated with U.S. Pat. No. 4,791,464 will be even more severe in such a structure however, because of the increased area of the depletion regions due to the requirement for them to run along the entire length of the device, so that a body contact electrode can be accommodated. U.S. Pat. No. 4,809,056 also describes a device in which the potential of the body can be controlled by means of an additional contact. Once again, the regions with opposite doping polarity to the source and drain regions run the entire length of the device, resulting in large depletion regions.

US statutory invention registration H1435 describes a device that solves the problem of leakage at the island edges and enables control of the potential of the body of the device. As shown in FIG. 14 of the accompanying drawings, the channel region 1402 is extended outside the gate electrode 1404 on both sides, and contacts are made to the p+ doped regions 1406. The disadvantage of this approach is the area consumed by the need for the two additional contacts.

Although the prior art therefore describes techniques for reducing the leakage current associated with the edges of the semiconductor islands, there are significant disadvantages either in terms of manufacturing difficulty, yield, increased size, increased sensitivity to ambient conditions, degraded high frequency performance, or a combination of these.

### SUMMARY OF INVENTION

According to a first aspect of the invention there is provided a thin film transistor formed in an island of semiconductor material disposed on an insulating substrate, the transistor comprising: a source region of a first conductivity type and a first doping concentration; a drain region of the first conductivity type and a second doping concentration; a first channel of a second conductivity type opposite the first conductivity type and a third doping concentration less than each of the first and second concentrations, the first channel extending in a first direction, parallel to a main conduction path, between the source and drain regions; a first insulated gate extending in a second direction substantially perpendicular to the first direction and substantially overlapping the first channel; and a first isolation diode which is substantially non-overlapping with the first gate and which comprises a first region of a fourth doping concentration less than each of the first and second concentrations extending in the first direction from the first channel by less than the length of the drain region in the first direction and in the second direction from a first edge of the drain region, and a second region of the second conductivity type and of a fifth doping concentration greater than the fourth concentration extending in the first direction from the first channel by less than the length of the drain region in the first direction and in the second direction from the first region such that the first and second regions form a p-n junction with the drain in the second direction but not in the first direction.

The transistor may comprise a second isolation diode which is non-overlapping with the first gate and which comprises a first region of the fourth concentration extending in the first direction from the first channel by less than the length of the drain region in the first direction, and a second region of the second conductivity type and of the fifth concentration extending in the first direction from the first channel by less than the length of the drain region in the first direction and in the second direction from the first region of the second diode such that the first and second regions of the second diode form a p-n junction with the drain in the second direction but not in the first direction.

The transistor may comprise third and fourth isolation diodes which are non-overlapping with the first gate and which comprise first regions of the fourth concentration extending in the first direction from the first channel by less than the length of the source region in the first direction, and in the second direction from first and second edges, respectively, of the source region, and second regions of the second conductivity type and of the fifth concentration extending in the first direction from the first channel by less than the length of the source region in the first direction and in the second direction from the first regions of the third and fourth diodes such that the first and second regions of each of the third and fourth diodes form a p-n junction with the source in the second direction but not in the first direction.

The first and second regions of the or each diode may extend from the first channel by substantially the same length in the first direction.

The first region of the or each diode may be of the second conductivity type.

The first region of the or each diode may be of the first conductivity type.

The fourth concentration may be substantially equal to the third concentration.

The second concentration may be substantially equal to the first concentration.

The transistor may comprise a second insulated gate overlapping the first insulated gate with the first channel disposed therebetween.

The transistor may comprise a second channel overlapped by at least one further insulated gate and provided with at least one further isolation diode.

The source and drain regions may be connected to the first channel by source and drain sub-regions, respectively, of reduced width in the second direction. The width of the drain sub-region may be less than the width of the source sub-region.

The or each diode may comprise a third region of the second conductivity type and of a sixth doping concentration less than the fifth concentration extending in the first direction from the first or second channel and in the second direction from the second region, and a fourth region of the first conductivity type extending in the first direction from the first or second channel and in the second direction from the third region.

At least one of source and drain regions may be connected to the first or second channel by a region of the first conductivity type and of a seventh doping concentration less than the first or second concentration. The region of the first conductivity type may be overlapped by at least one of the gates.

The first channel may be connected to a body contact.

According to a second aspect of the invention, there is provided an active matrix display comprising a plurality of transistors, each according to the first aspect of the invention.

It is thus possible to provide diodes that isolate the regions of a TFT channel at the edges of a semiconductor island from the source and drain to reduce or eliminate the leakage current associated with the early turn-on of the semiconductor island edges. The island is patterned in such a way that the area of the depletion regions associated with the isolation diodes is reduced or minimised.

An example of such a TFT comprises:
An island of semiconductor material positioned on an insulating substrate, the island having a top surface and side walls.
At least one gate stack comprising a gate electrode and a gate insulator layer that separates the electrode from the semiconductor island, positioned above or below, or above and below the semiconductor island.
A channel region of a second conductivity type within the semiconductor island, positioned above/below the gate electrode and extending to the side walls.
Source and drain regions of a first conductivity type within the semiconductor island on either side of the channel region.
Isolation diodes within the semiconductor island not overlapped by the gate electrode(s) and comprising two regions. The first region is positioned adjacent to the source/drain and the channel region and is of the same conductivity type and doping concentration as the channel region. The second region extends to the side wall and is also of the second conductivity type, with a doping concentration that that is significantly higher than the first region.
The semiconductor island patterned in such a way that the regions which contain the isolation diodes are minimised in area.

Thus, the areas (not covered by the gate electrode) where depletion regions form between n-type and p-type semiconductor material are reduced or minimised in size.

Rather than being formed within the existing semiconductor island, the isolation diodes are formed in additional semiconductor regions that extend the transistor in the width direction (parallel to the gate electrode). The additional regions do not run the entire length of the device, existing underneath the gate electrode and extending only a short distance beyond this in the transistor length direction (perpendicular to the gate electrode).

The implant that is used to create the highly doped source and drain regions for pTFTs can also be used to create the heavy p-type doping in the isolation diodes of the nTFT when a complementary fabrication process is used. The nTFT source/drain implant can likewise be used to create the heavy n-type doping in the isolation diodes of the pTFT so that no additional process steps are required.

Because the area of the depletion region associated with the isolation diodes is reduced or minimised, the leakage current of the diodes is also reduced or minimised, which allows a smaller TFT off state current to be achieved. In addition, the parasitic capacitance of the depletion regions is also reduced or minimised, ensuring that the impact of these regions on performance when the TFT is operated at high frequency is reduced. Sensitivity to illumination and temperature, in the form of elevated diode leakage currents, is also reduced or minimised.

When forming isolation diodes on a semiconductor island patterned in the manner described herein, the alignment of two implantation masks for n+ and p+ doping is only critical in one direction (the x direction in FIG. 12), rather than two. This simplifies the fabrication of the TFTs and thus allows reduced cost and/or improved yield in comparison to the prior art.

The isolation scheme may be combined with a structure that acts to control the channel potential of the TFT. Whilst such structures can prevent leakage current at the Si island edges if they are added to both sides of the channel, this typically consumes a significant amount of area. As only one contact is needed to control the channel potential, the addition of a minimised area isolation diode of the type disclosed here to the other side of the TFT yields the advantages of channel potential control and leakage elimination in a more efficient manner than any of the prior art.

The foregoing and other objectives, features, and advantages of the invention will be more readily understood upon consideration of the following detailed description of the invention, taken in conjunction with the accompanying drawings.

### BRIEF DESCRIPTION OF DRAWINGS

FIG. 1 shows a known AMLCD;

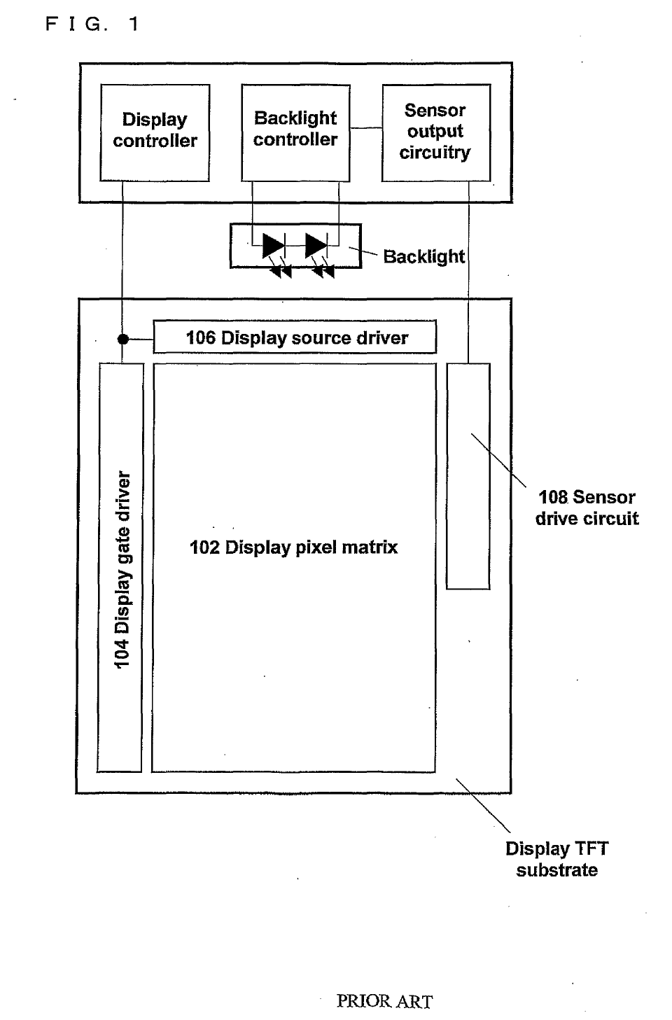

FIG. 2 shows a known typical TFT with the top-gate configuration;

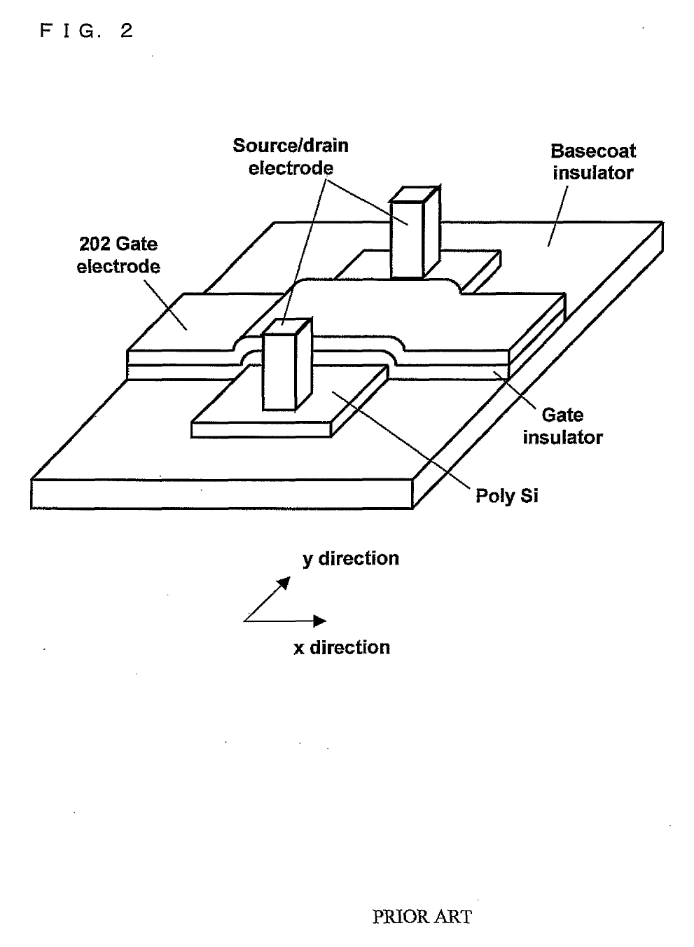

FIG. 3 shows a cross-section through a known nTFT with top and bottom gate electrodes;

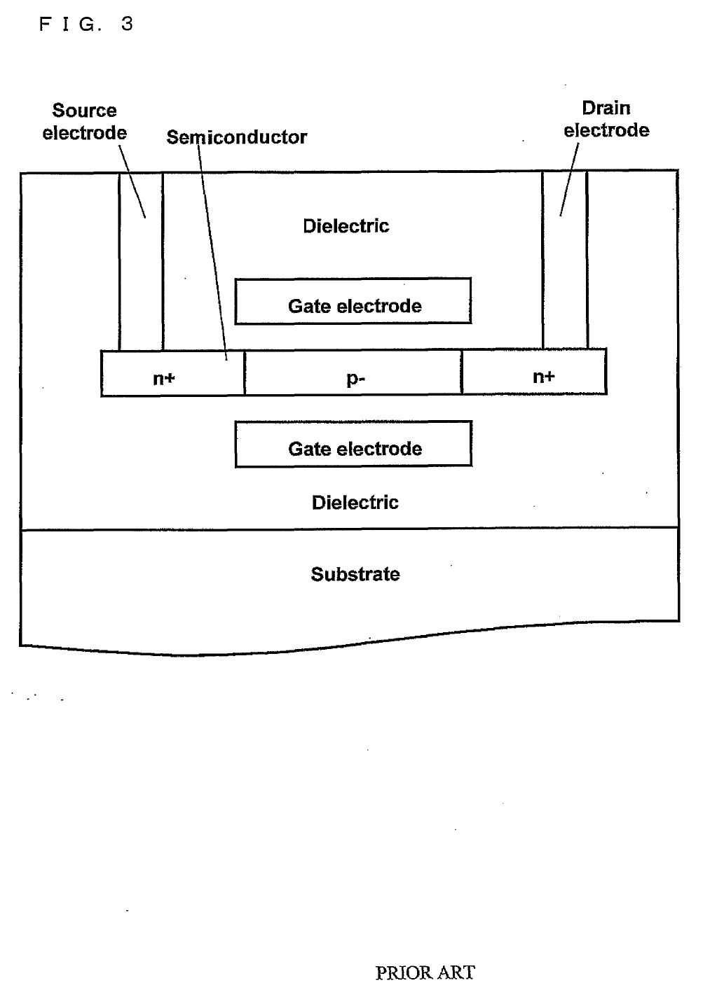

FIG. 4 is a plan view of a known TFT with narrow width, suitable for logic applications;

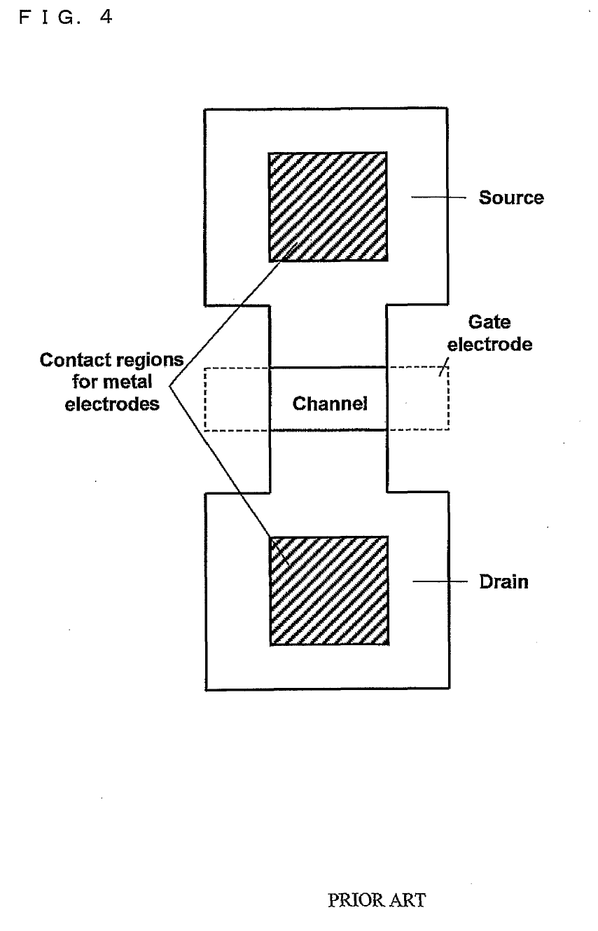

FIG. 5 shows a cross-section through a known nTFT;

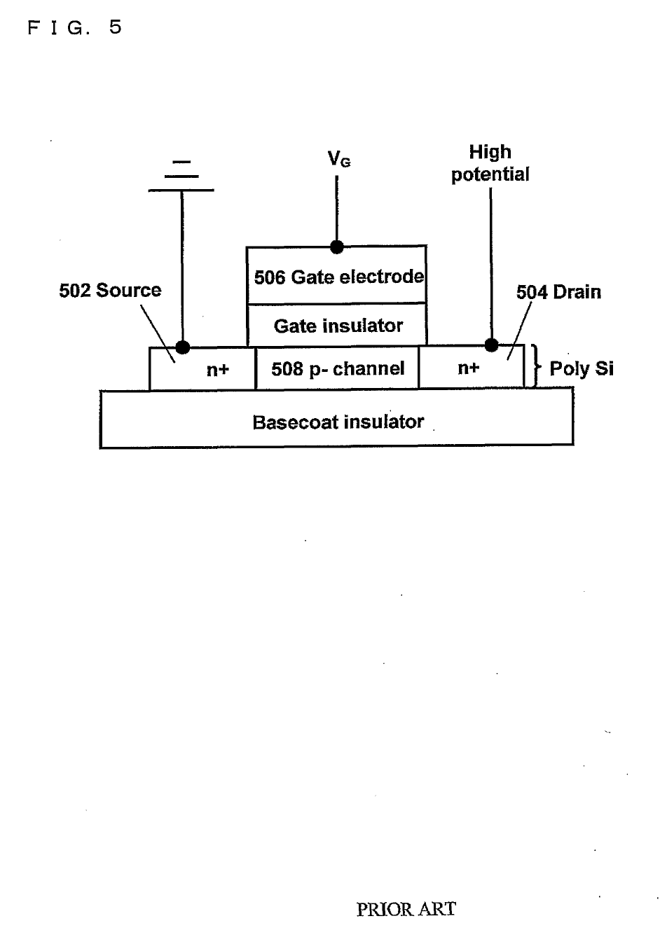

FIG. 6 shows known typical TFT transfer characteristics;

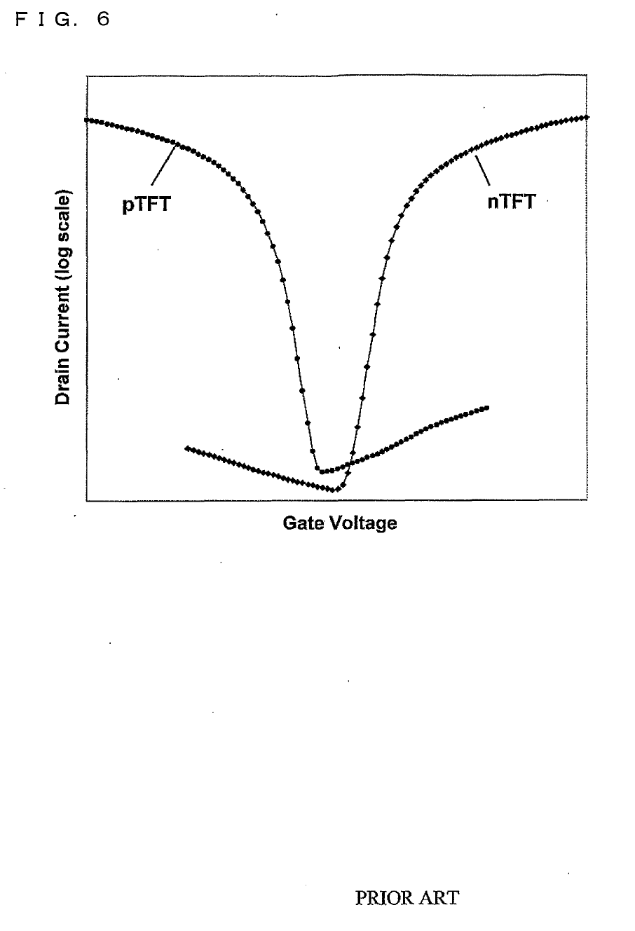

FIG. 7 shows cross-sections through known nTFTs with LDD and GOLD structures;

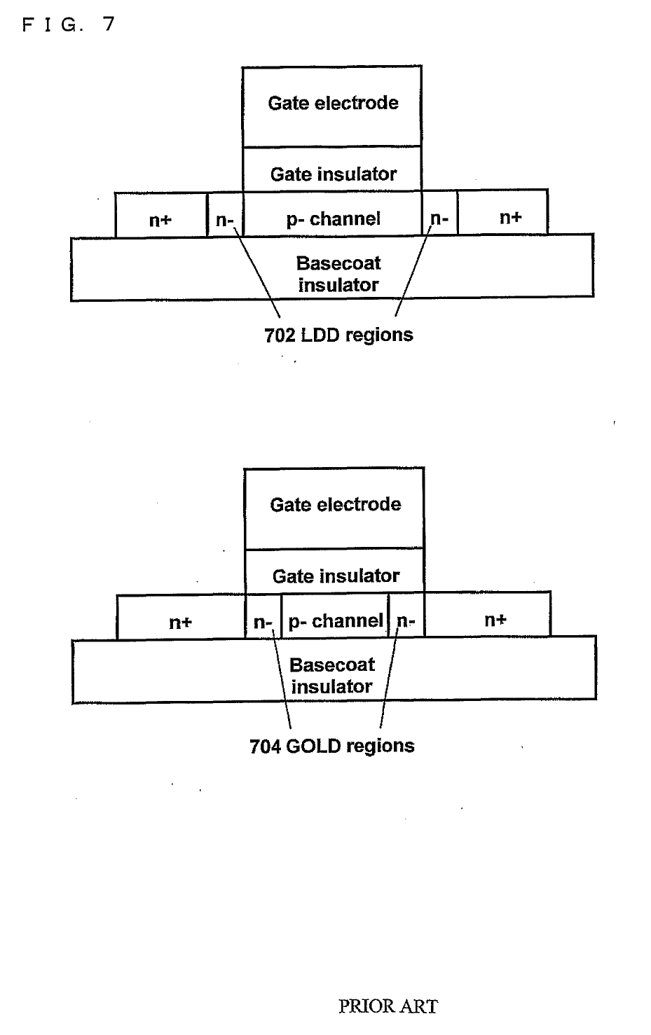

FIG. 8 shows known TFT transfer characteristics where the nTFT suffers from subthreshold leakage;

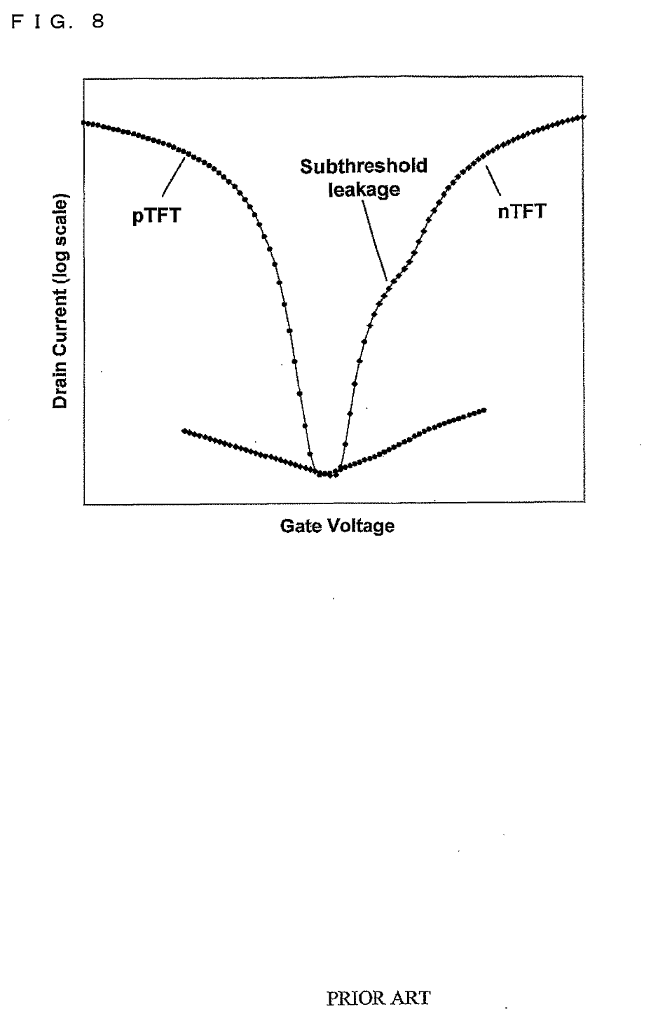

FIG. 9 shows an equivalent circuit of a known TFT with parasitic conduction at the island edges;

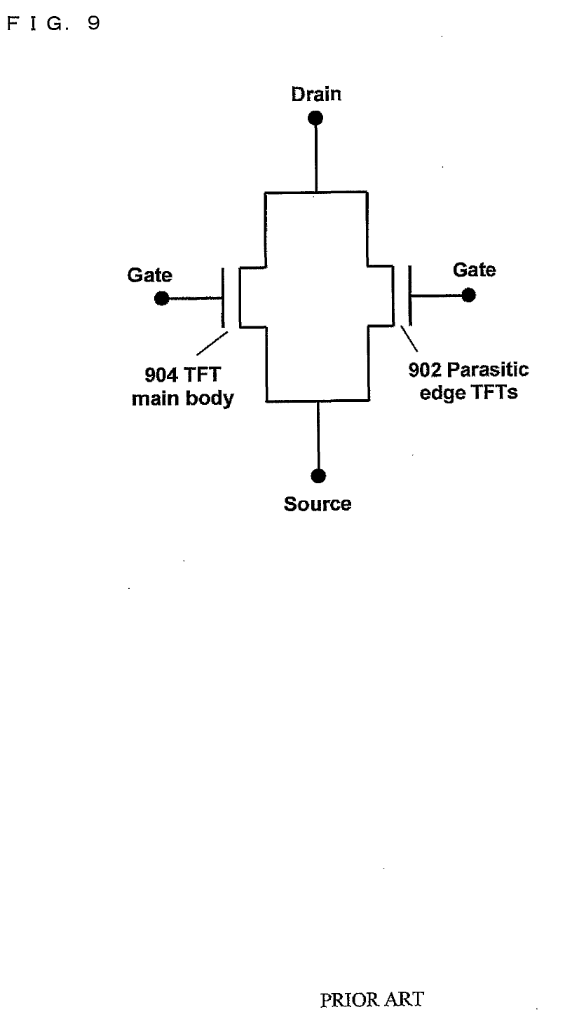

FIG. 10 shows is a plan view of a known TFT using the isolation scheme described by U.S. Pat. No. 4,791,464;

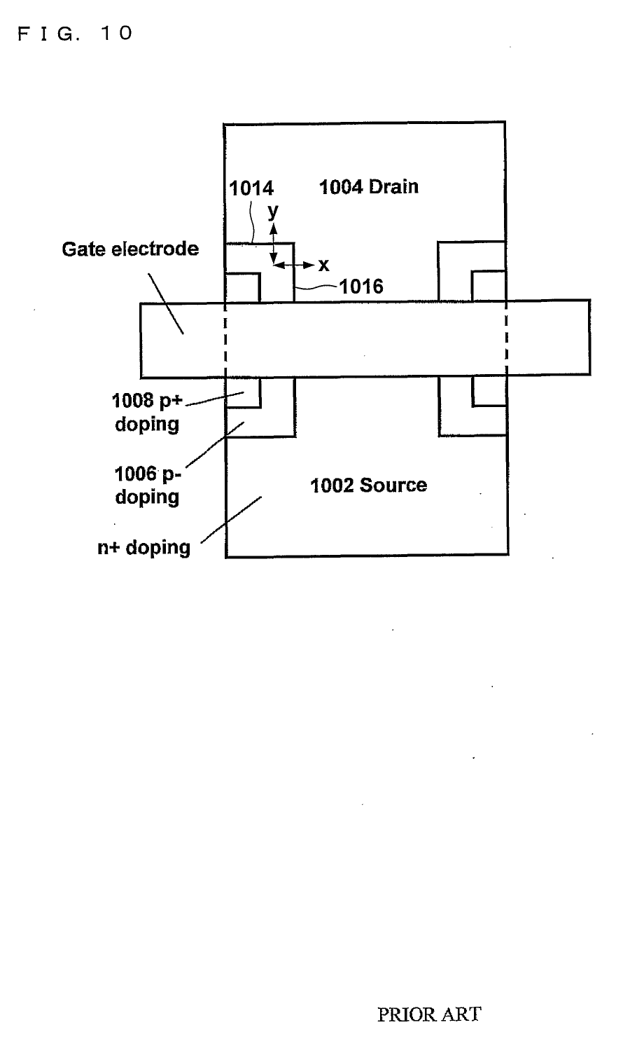

FIG. 11 shows an equivalent circuit of a known TFT with the diodes introduced in U.S. Pat. No. 4,791,464 to prevent leakage at the island edges;

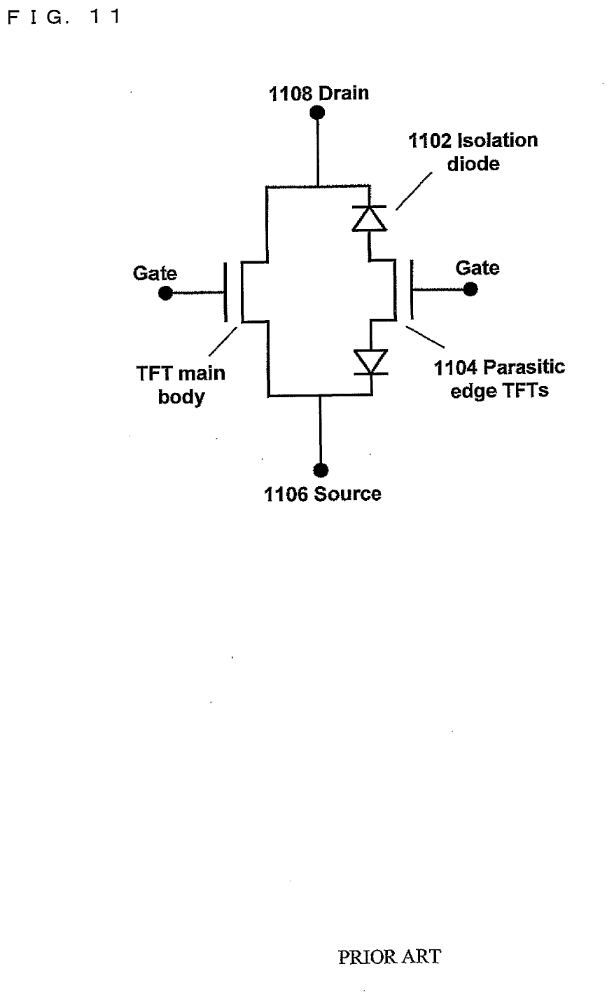

FIG. 12 illustrates a requirement to precisely align two doping masks to form the structure described by U.S. Pat. No. 4,791,464;

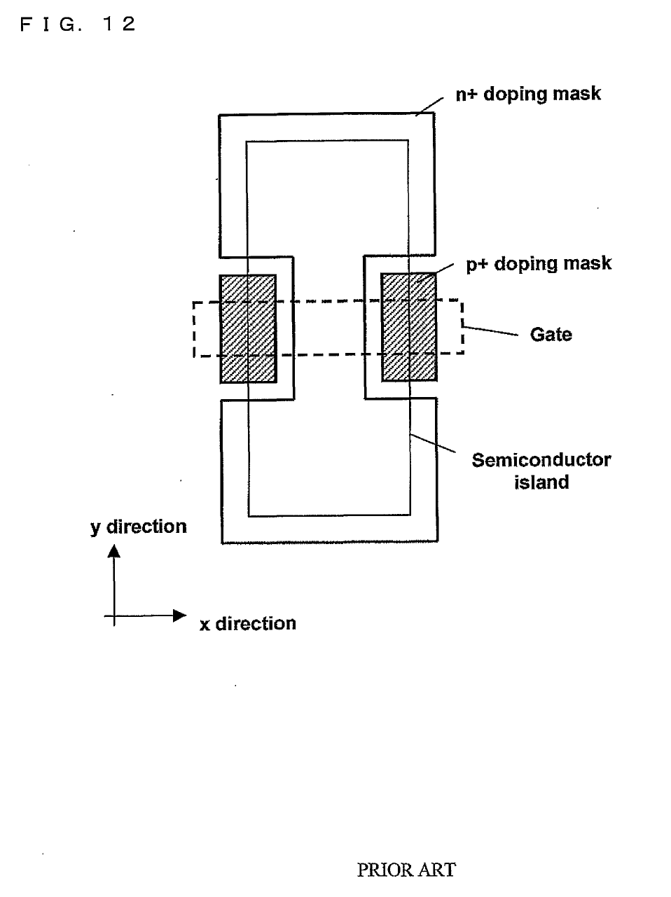

FIG. 13 shows a known TFT with additional regions for hot carrier removal described by U.S. Pat. No. 6,940,138;

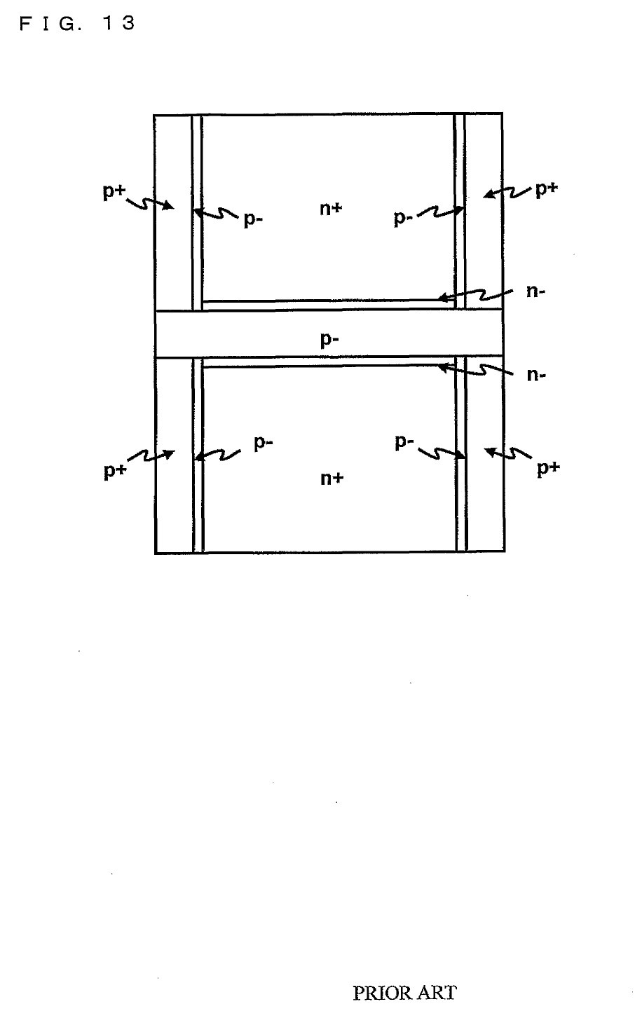

FIG. 14 is a plan view of a known TFT described in US statutory invention registration H1435;

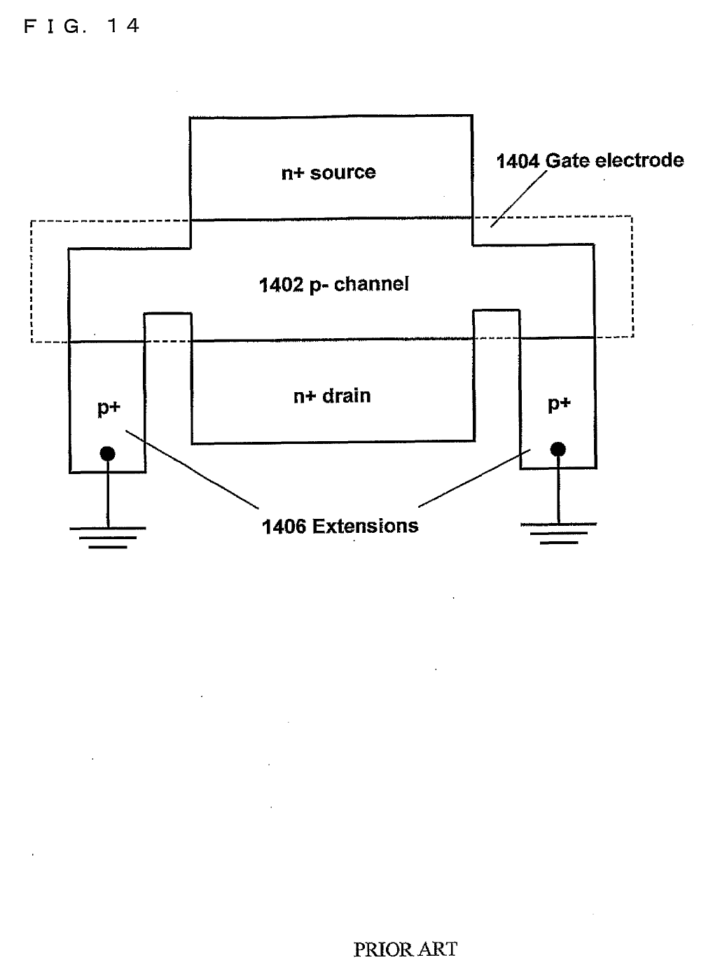

FIG. 15 shows the first embodiment of the invention;

FIG. 16 shows the first embodiment of the invention for the case of narrow channel TFTs;

FIG. 17 shows the second embodiment of the invention;

FIG. 18 shows the third embodiment of the invention;

FIG. 19 shows the fourth embodiment of the invention;

FIG. 20 shows the fifth embodiment of the invention;

FIG. 21 shows the sixth embodiment of the invention;

FIG. 22 shows the seventh embodiment of the invention;

FIG. 23 shows the eighth embodiment of the invention; and

FIG. 24 shows a ninth embodiment of the invention.

### DESCRIPTION OF EMBODIMENTS

The first embodiment describes a TFT with the semiconductor island patterned in such a way as to minimise the area of the depletion region of the isolation diodes.

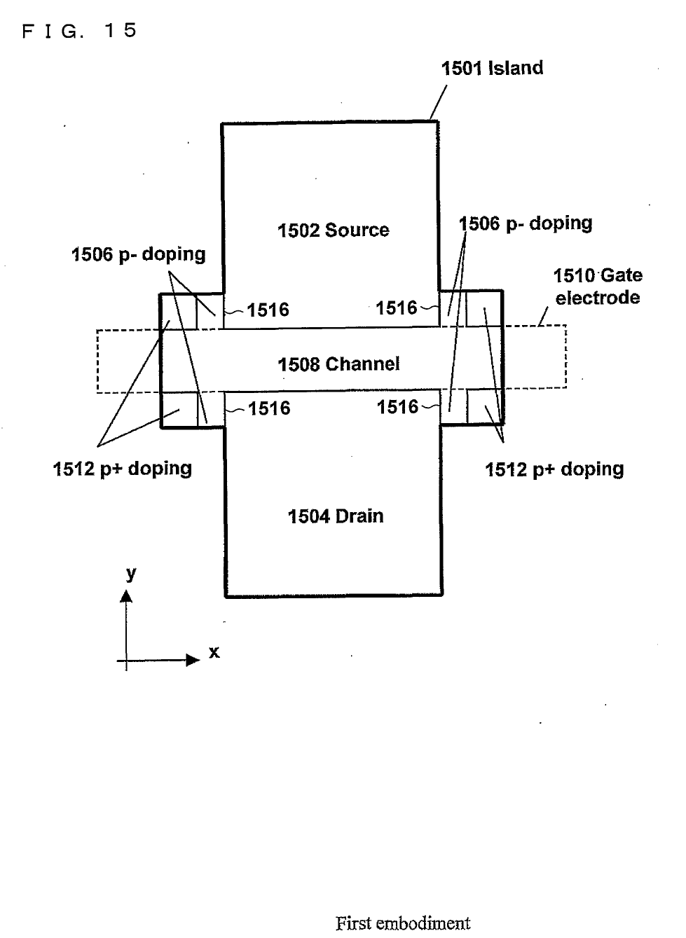

FIG. 15 illustrates the embodiment in plan view for the case of an nTFT with a relatively wide channel. The TFT comprises a thin film of semiconductor (most likely Si: either amorphous, polycrystalline or crystalline) and a gate electrode that may be positioned above or below the semiconductor, separated from it by a dielectric such as SiO₂. Additionally there may be two gate electrodes positioned above and below the semiconductor island, either of which may be left floating rather than being connected to a supply voltage.

In the semiconductor island 1501, the source 1502 and drain 1504 regions are heavily n-type doped (to have first and second doping concentrations which are typically substantially equal) and are separated by the channel region 1508, which lies directly above or below the gate electrode 1510 (or is sandwiched between two gate electrodes, depending on the type of TFT) and is doped weakly p-type. The channel region 1508 is extended in both directions parallel to that of the gate electrode 1510 (x direction in FIG. 15), so that it protrudes beyond the edges of the source 1502 and drain 1504. The protrusions are also extended in both directions perpendicular to the gate electrode 1510 (y direction in FIG. 15). These extensions that do not lie directly above or below the gate electrode 1510 comprise a lightly p-type doped region 1506, which is adjacent to the source 1502 or drain 1504 depending on which side of the channel 1508 it is positioned, and a heavily doped p-type region 1512 that lies adjacent to the lightly doped region 1506. The lightly doped regions 1506 have the same doping concentration as the channel region 1508.

Isolation diodes of the type described in U.S. Pat. No. 4,791,464 are thus formed in the extended regions not covered by the gate electrode. The area of the depletion regions that form between n and p-type regions is determined by the extent by which the island extensions protrude from the gate electrode in the y direction. The minimum possible protrusion is determined by the alignment capability of the lithographic system that is used in fabrication. The regions 1506, 1512 form p-n junctions 1516 with the source 1502 and the drain 1504 in the (“second”) direction x but not in the (“first”) direction y parallel to the main conduction path of the TFT. The regions 1506, 1512 extend from the channel 1508 by substantially the same length in the first direction.

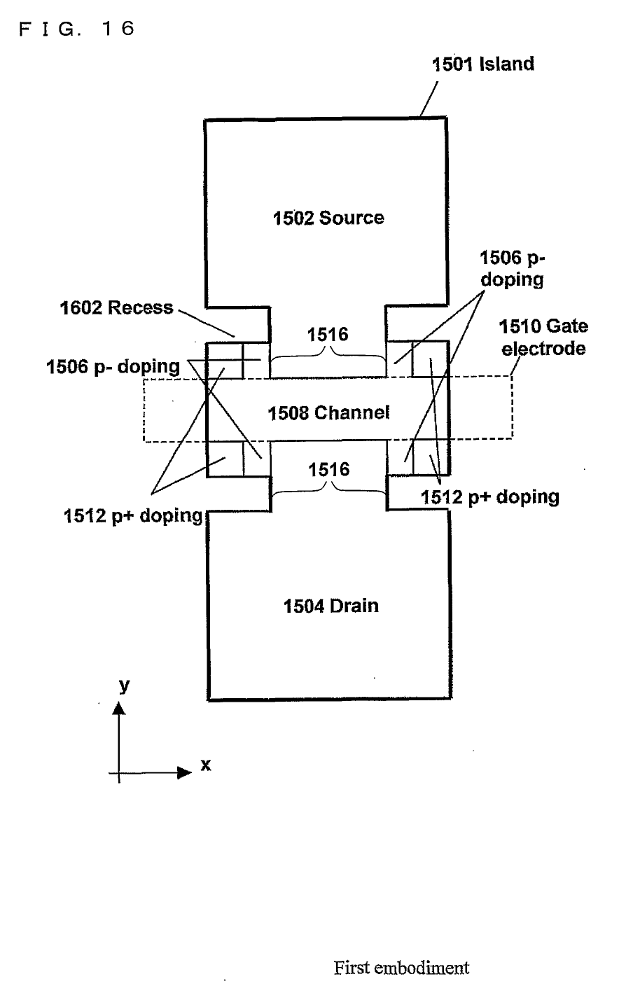

For logic applications, the TFT channel is often narrow, so that the regions where the source and drain electrodes contact to the semiconductor may be significantly wider than the channel. In such a case, the semiconductor island 1501 is patterned as shown in FIG. 16. The same principle of forming the isolation diodes in island extensions is used. In this case however, the source 1502 and drain 1504 regions are also extended parallel to the gate electrode 1510 (x direction) to create a region large enough for a metal contact to the semiconductor. Recesses 1602 in the semiconductor are left between these source/drain extensions and the p-type regions 1506 and 1512. The source 1502 and the drain 1504 are thus connected to the channel by source and drain sub-regions of reduced width (in the x direction).

The advantage of this embodiment over the prior art is that, in both the semiconductor island shapes introduced here, the depletion region of the diodes is minimised as far as possible. This reduces the reverse leakage current associated with the diodes, allowing small off state currents to be achieved. The sensitivity of the TFT to changes in illumination and temperature and the parasitic capacitance of the isolation diodes are reduced.

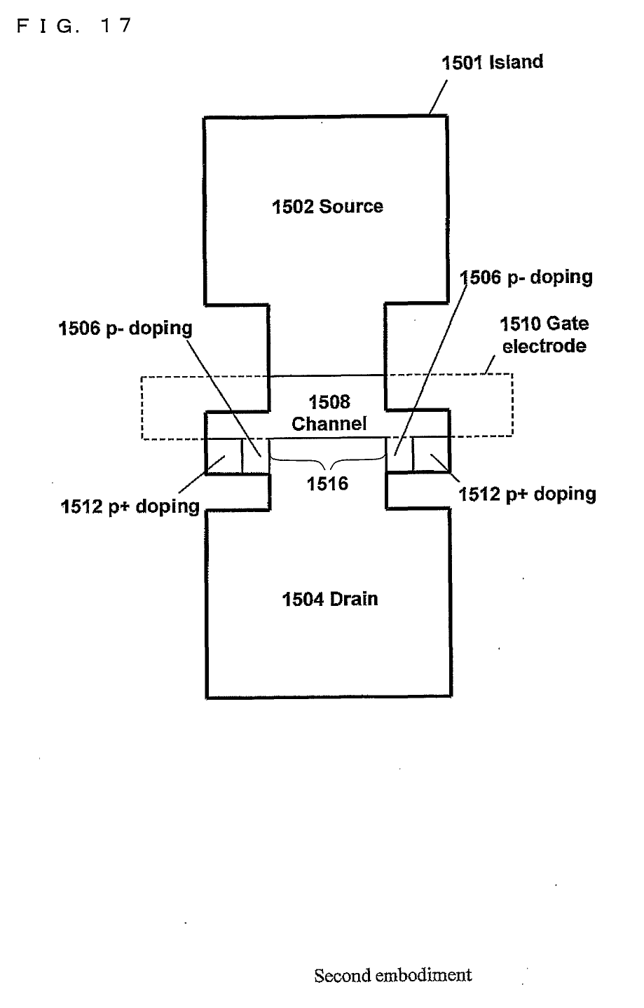

In the second embodiment of the invention, the TFT is formed as described in the first embodiment, but the isolation diodes are formed only on the drain 1504 side of the device, as shown in FIG. 17. This embodiment is particularly useful in logic applications, in which the potential on the source and drain is usually fixed so that minority carriers (electrons in an nTFT) always flow towards the drain. The isolation diodes are formed in the same way as in the first embodiment, with regions of p-type doping 1506 of the same concentration as the channel 1508 underneath the gate electrode 1510 adjacent to the heavily n-type doped drain 1504 for an nTFT. Heavily p-type doped regions 1512 are positioned adjacent to the lower doped regions 1506. The channel 1508 reduces to the width of the source region 1502 underneath the gate electrode 1506.

This embodiment preserves all the advantages of the first embodiment, but in the specific case that current flow in the TFT is always in the same direction, the parasitic capacitance associated with the isolation diodes is further reduced by removing them from the source side.

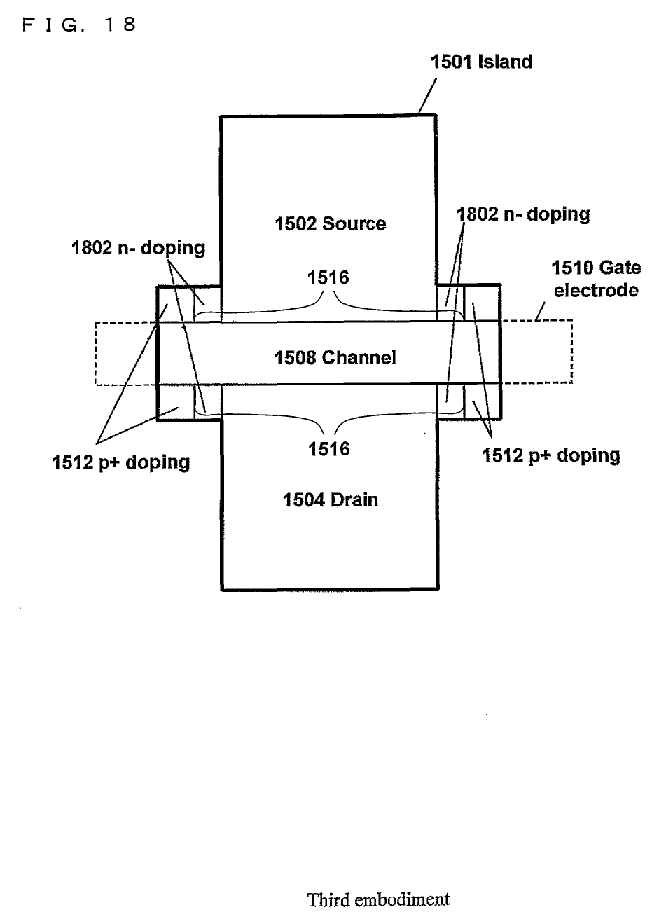

In the third embodiment of the invention, the TFT is formed exactly as described in either of the first two embodiments, but the lightly doped p-type regions 1506 between the heavily doped n-type and p-type regions that are not covered by the gate electrode are replaced with lightly doped n-type regions 1802 as shown in FIG. 18.

The third embodiment has the advantages that such a device is compatible with a process flow that includes a global n-type ion implantation step subsequent to the formation of the gate electrode, which would override the low doped p-type regions 1506. Switching the polarity of the low doped regions does not affect the operation of the isolation diodes; the important point is that a low doped region must exist, whether it is n-type or p-type.

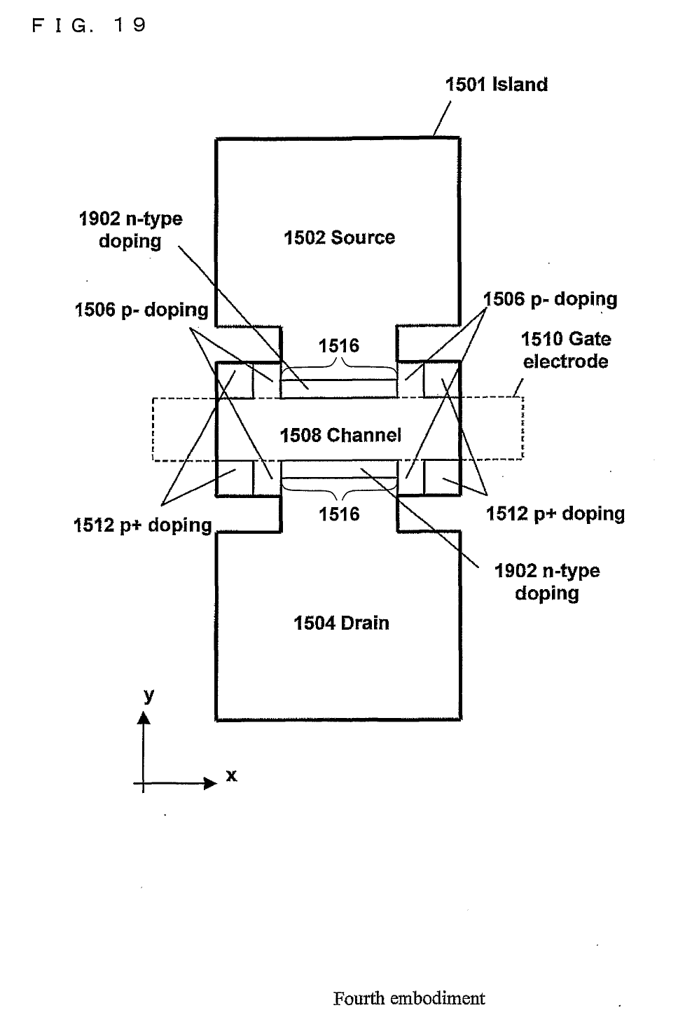

In the fourth embodiment of the invention, the TFT is formed as described in any of the previous three embodiments, with the addition of lightly doped drain (LDD) structures 1902 as shown in FIG. 19. In the case of an nTFT, LDD takes the form of additional n-type regions 1902 inserted between the heavily doped source 1502 and drain 1504 regions and the p-type channel 1508, adjacent and self-aligned to the gate electrode 1510. The LDD structures may extend beyond the p-type regions 1506 (or n-type regions in the case of a TFT as described in the third embodiment) in the direction perpendicular to the gate electrode (y direction) or need not extend so far, as illustrated in FIG. 19. In the case that the LDD structures 1902 extend beyond the p-type regions 1506, the doping concentration of these regions may be increased to the same level as the p+ regions 1512.

This embodiment combines the advantages of isolation diodes with minimised depletion regions and LDD structures.

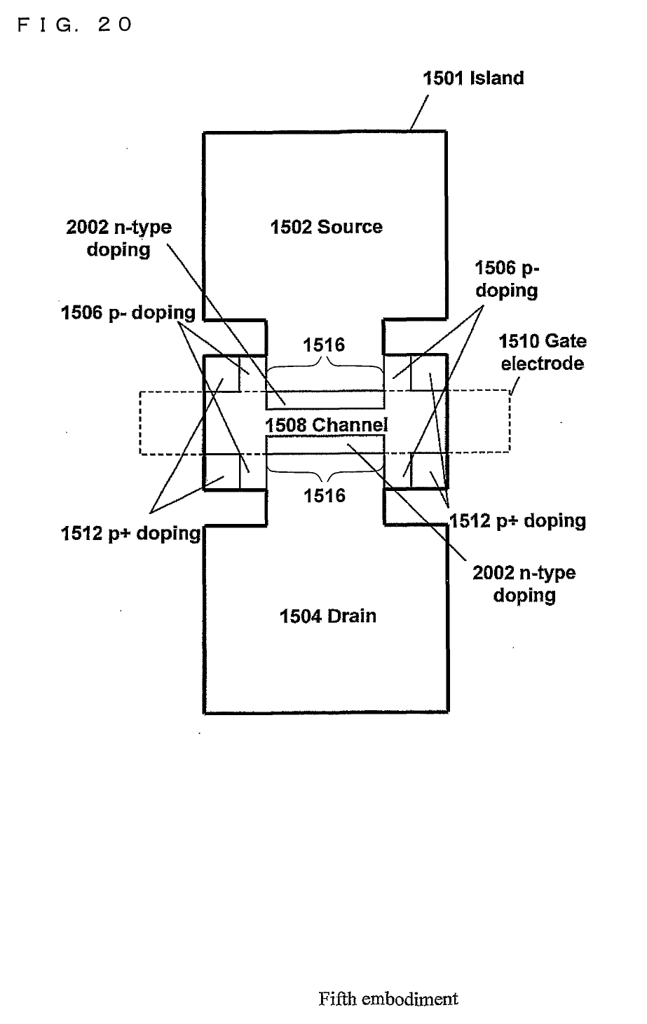

In the fifth embodiment, the TFT is formed as described in any of the first three embodiments, with the addition of gate overlapped drain (GOLD) structures 2002, as shown in FIG. 20. In the case of an nTFT, GOLD takes the form of additional n-type regions 2002 inserted between the heavily doped source 1502 and drain 1504 regions and the p-type channel 1508 that is underneath the gate electrode 1510. In contrast to LDD, GOLD structures are formed underneath the gate electrode. They may also be employed on both sides of the channel or only on the drain side, depending on the application of the TFT.

The fifth embodiment combines the advantages of isolation diodes with minimised depletion regions and GOLD structures.

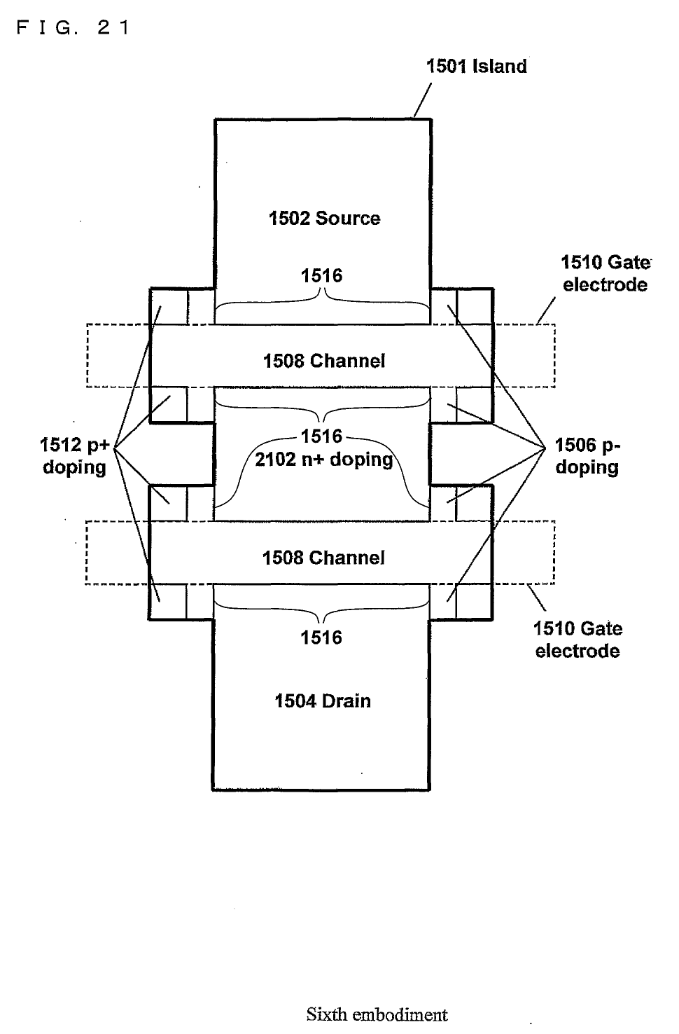

In the sixth embodiment, the TFT is formed as described in any of the previous five embodiments but includes two or more gate electrodes 1510, as shown in FIG. 21. The region(s) 2102 between gate electrodes 1510, has/have doping of the same polarity and concentration as the source 1502 and drain 1504 regions, and may also include LDD regions as described in the fourth embodiment if required. Semiconductor island extensions containing isolation diodes may be employed on both sides or only on the drain side of each gate electrode.

TFTs with multiple gate electrodes are useful when there is a requirement to minimise off-state leakage. The sixth embodiment combines the advantages of minimised diode depletion region area with reduced off-state leakage due to the employment of multiple gates.

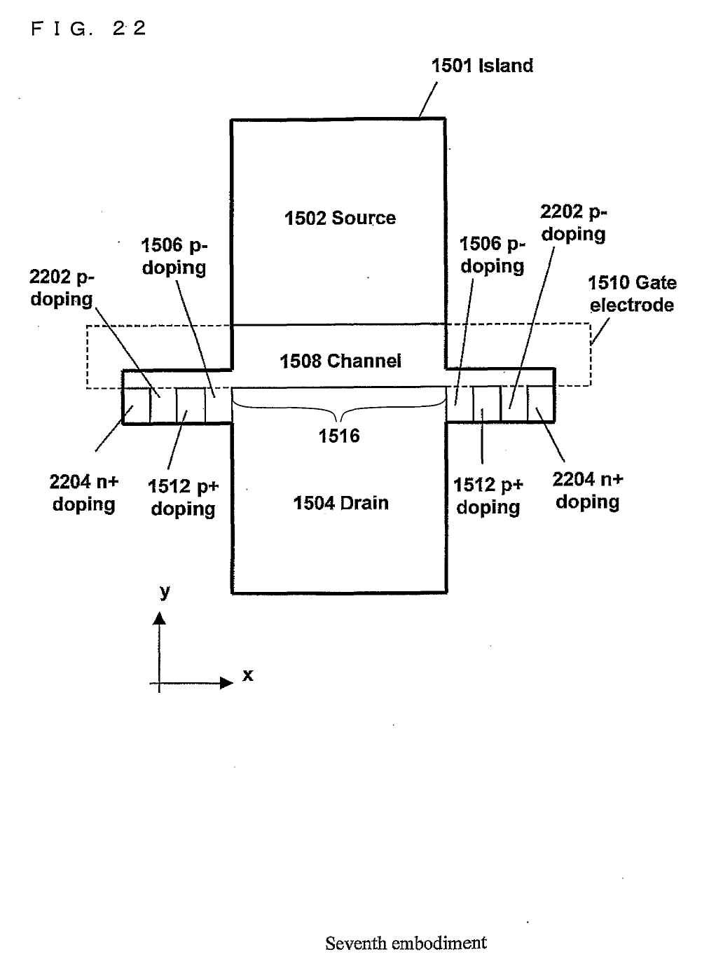

In the seventh embodiment, the TFT is formed as described in the second embodiment, but the isolation regions are formed by two diodes placed back to back, as shown in FIG. 22. The channel region 1508 is further extended parallel to the gate electrode (x direction) in the region of the isolation diodes and, in the case of an nTFT, additional p− regions 2202 are placed adjacent to the p+ regions 1512. Heavily n-type doped regions 2204 are placed adjacent to the low doped p-type regions 2202. Either or both of the p− regions 1506, 2202 in the island extension may be exchanged for n− regions, as introduced in the third embodiment. The seventh embodiment may also be combined with the fourth, fifth or sixth embodiments, if LDD, GOLD or multiple gate electrodes are required.

This embodiment is useful in the case of applications which require that the source and drain may switch roles during operation (i.e. the source may be biased so that it acts as the drain). The presence of two diodes ensures that one of them will always be reverse biased, isolating the island edges from the main device. In contrast to employing isolation diodes on both sides of the gate electrode, as introduced in the first embodiment, this approach allows further reduction of the parasitic components that can degrade high frequency performance.

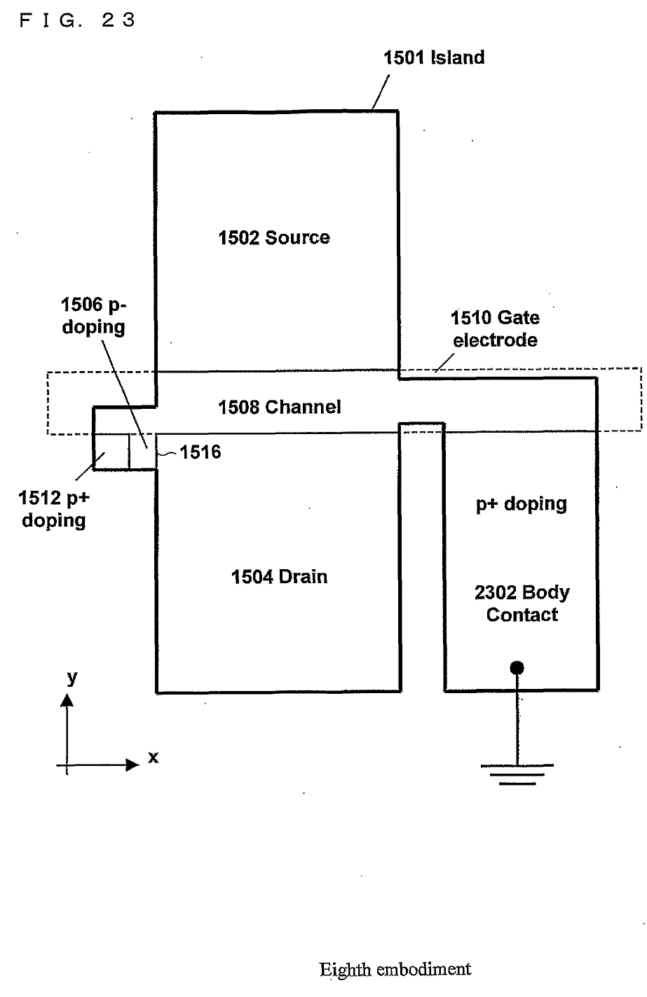

In the eighth embodiment, the TFT is formed with the isolation region on one side (in the x direction) only. The isolation region is as described in any of embodiments one to three inclusive. In FIG. 23 the isolation region has been drawn as described in the second embodiment, so that it is only on the drain 1504 side of the gate electrode 1510. On the other side of the TFT (in the x direction), the channel region 1508 underneath the gate electrode 1510 is extended in the x direction. A body contact region 2302 is then placed adjacent to this extended region so that it extends beyond the gate electrode 1510 in the y direction and is contacted by a metal electrode. In practice, region 2302 will likely extend as far as the limit of the source 1502 or drain 1504 (depending on which side of the gate electrode 1510 it is positioned), since the requirement for it to be contacted with an electrode will dictate that the same minimum amount of semiconductor material is present. In the case of an nTFT, the body contact region 2302 is doped heavily p-type in the area that is not covered by the gate electrode 1510. The body contact region 2302 is grounded in order to prevent the kink effect that may be observed when the channel region of the TFT is floating.

The eighth embodiment may be combined with LDD or GOLD structures, as disclosed in the fourth and fifth embodiments.

Because this embodiment incorporates a contact to the TFT body, the channel potential may be controlled to reduce undesirable operation such as the kink effect. The eighth embodiment enjoys the advantages of a body contact, whilst reducing consumed area as far as possible by employing a minimised area isolation diode on the other side of the channel.

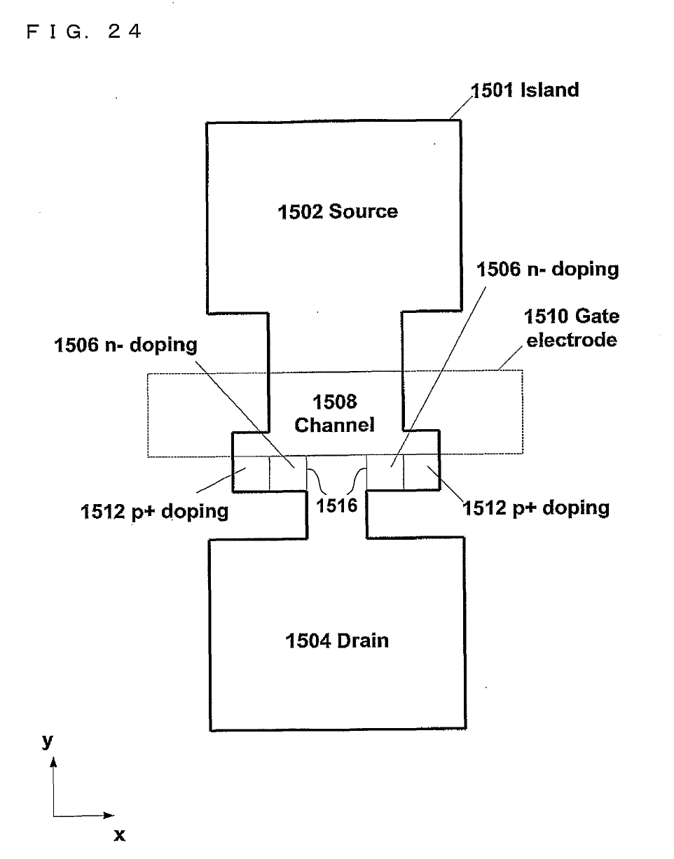

In the ninth embodiment shown in FIG. 24, the TFT differs from that shown in FIG. 17 in that the regions 1506 are weakly n-type doped (as in the TFT shown in FIG. 18) and the width (in the x direction) of the drain sub-region connected to the channel 1508 is less than that of the source sub-region. The channel region 1508 overlapped by the gate electrode 1510 extends in the x direction so that its width changes from being equal to the width of the source 1502 to being equal to the combined width of the drain 1504, the two n-type regions 1506 and the two p-type regions 1512.

The advantage of this embodiment arises because the width of the drain is reduced relative to the source, so that the total width of the drain and the two isolation diodes is also reduced. The area of the channel region underneath the gate electrode is in turn reduced, as it does not need to extend so far to encompass the width of the drain and isolation diodes. This minimises the parasitic gate capacitance, enabling faster switching times for digital applications. The advantages of minimised parasitic capacitance outweigh any disadvantage of increased series resistance that results from the reduced drain width in at least some applications.

The problem with leakage at the island edges can equally affect pTFTs and nTFTs. The TFT may therefore be formed as described in any of the previous embodiments, but the polarity of every doping region may be reversed, with the relative doping concentrations remaining the same. This provides a pTFT.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A thin film transistor formed in an island of semiconductor material disposed on an insulating substrate, the transistor comprising: a source region of a first conductivity type and a first doping concentration; a drain region of the first conductivity type and a second doping concentration; a first channel of a second conductivity type opposite the first conductivity type and a third doping concentration less than each of the first and second concentrations, the first channel extending in a first direction, parallel to a main conduction path, between the source and drain regions; a first insulated gate extending in a second direction substantially perpendicular to the first direction and substantially overlapping the first channel; and a first isolation diode which is substantially non-overlapping with the first gate and which comprises a first region of a fourth doping concentration less than each of the first and second concentrations extending in the first direction from the first channel by less than the length of the drain region in the first direction and in the second direction from a first edge of the drain region, and a second region of the second conductivity type and of a fifth doping concentration greater than the fourth concentration extending in the first direction from the first channel by less than the length of the drain region in the first direction and in the second direction from the first region such that the first and second regions form a p-n junction with the drain in the second direction but not in the first direction.

2. A transistor as claimed in claim 1, comprising a second isolation diode which is non-overlapping with the first gate and which comprises a first region of the fourth concentration extending in the first direction from the first channel by less than the length of the drain region in the first direction, and a second region of the second conductivity type and of the fifth concentration extending in the first direction from the first channel by less than the length of the drain region in the first direction and in the second direction from the first region of the second diode such that the first and second regions of the second diode form a p-n junction with the drain in the second direction but not in the first direction.

3. A transistor as claimed in claim 1, comprising third and fourth isolation diodes which are non-overlapping with the first gate and which comprise first regions of the fourth concentration extending in the first direction from the first channel by less than the length of the source region in the first direction, and in the second direction from first and second edges, respectively, of the source region, and second regions of the second conductivity type and of the fifth concentration extending in the first direction from the first channel by less than the length of the source region in the first direction and in the second direction from the first regions of the third and fourth diodes such that the first and second regions of each of the third and fourth diodes form a p-n junction with the source in the second direction but not in the first direction.

4. A transistor as claimed in claim 1, in which the first and second regions of the or each diode extend from the first channel by substantially the same length in the first direction.

5. A transistor as claimed in claim 1, in which the first region of the or each diode is of the second conductivity type.

6. A transistor as claimed in claim 1, in which the first region of the or each diode is of the first conductivity type.

7. A transistor as claimed in claim 1, in which the fourth concentration is substantially equal to the third concentration.

8. A transistor as claimed in claim 1, in which the second concentration is substantially equal to the first concentration.

9. A transistor as claimed in claim 1, comprising a second insulated gate overlapping the first insulated gate with the first channel disposed therebetween.

10. A transistor as claimed in claim 1, comprising a second channel overlapped by at least one further insulated gate and provided with at least one further isolation diode.

11. A transistor as claimed in claim 1, in which the source and drain regions are connected to the first channel by source and drain sub-regions, respectively, of reduced width in the second direction.

12. A transistor as claimed in claim 11, in which the width of the drain sub-region is less than the width of the source sub-region.

13. A transistor as claimed in claim 1, in which the or each diode comprises a third region of the second conductivity type and of a sixth doping concentration less than the fifth concentration extending in the first direction from the first or second channel and in the second direction from the second region, and a fourth region of the first conductivity type extending in the first direction from the first or second channel and in the second direction from the third region.

14. A transistor as claimed in claim 1, in which at least one of source and drain regions is connected to the first or second channel by a region of the first conductivity type and of a seventh doping concentration less than the first or second concentration.

15. A transistor claimed in claim 14, in which the region of the first conductivity type is overlapped by at least one of the gates.

16. A transistor as claimed in claim 1, in which the first channel is connected to a body contact.

17. An active matrix display comprising a plurality of transistors, each as claimed in claim 1.
